(19) United States
(12) Patent Application Publication
(10) Pub. No.: US 2018/0166612 A1
(43) Pub. Date: Jun. 14, 2018

(54) LIGHT EMITTING DEVICE PACKAGE AND LIGHTING APPARATUS INCLUDING THE SAME

(71) Applicant: LG INNOTEK CO., LTD., Seoul (KR)

(72) Inventor: Min Ji JIN, Seoul (KR)

(73) Assignee: LG INNOTEK CO., LTD., Seoul (KR)

(21) Appl. No.: 15/560,956

(22) PCT Filed: Mar. 16, 2016
(86) PCT No.: PCT/KR2016/002608

§ 371 Date: Sep. 22, 2017

(30) Foreign Application Priority Data
Mar. 23, 2015 (KR) 10-2015-0040076

(51) Int. Cl. H01L 33/50; H01L 33/52

(52) U.S. Cl. CPC H01L 33/50; H01L 33/52

(57) ABSTRACT

A light emitting device package of one embodiment includes a base, a light emitting device disposed on the base and having a first refractive index, a wavelength conversion portion disposed on the light emitting device and having a second refractive index, and a buffering layer disposed between the light emitting device and the wavelength conversion portion and having a third refractive index between the first refractive index and the second refractive index.

### TECHNICAL FIELD

Embodiments relate to a light emitting device package and a lighting apparatus including the same.

### BACKGROUND ART

Light emitting diodes are one type of semiconductor device that converts electricity into infrared rays or light using the characteristics of compound semiconductors, in order to transmit or receive signals or to be used as a light source.

Group III-V nitride semiconductors are in the spotlight as a core material for light emitting devices such as, for example, light emitting diodes (LEDs) or laser diodes (LDs) thanks to the physical and chemical properties thereof.

Such light emitting diodes have excellent environmental friendliness because they include no environmentally harmful materials such as mercury (Hg), which has conventionally been used in lighting apparatuses such as, for example, incandescent lamps and fluorescent lamps, and also have other advantages, for example, a long lifespan and low power consumption. Therefore, existing light sources are being replaced with light emitting diodes. In case of the existing light emitting device package, the luminous flux of the light emitted from the light emitting device is continuously required to be improved.

### DISCLOSURE

### Technical Problem

Embodiments provide a light emitting device package and a lighting apparatus including the same having the improved luminous flux.

### Technical Solution

A light emitting device package according to an embodiment may include a base; a light emitting device disposed on the base and having a first refractive index; a wavelength conversion portion disposed on the light emitting device and having a second refractive index; and a buffering layer disposed between the light emitting device and the wavelength conversion portion and having a third refractive index between the first refractive index and the second refractive index.

For example, the third refractive index may be smaller than the first refractive index and larger than the second refractive index. Alternatively, the third refractive index may be smaller than the second refractive index and larger than the first refractive index. The buffering layer may include at least one of silicon, TiO₂, BaTiO₃, or ZrO₂.

For example, the wavelength conversion portion may have a film shape. The buffering layer may be a thickness of 50 μm to 70 μm. For example, the light emitting device package may further include a lens disposed on the base to surround the light emitting device and the wavelength conversion portion. The lens may have a hemispherical cross-sectional shape.

For example, the light emitting device may emit a light within a blue wavelength band. The buffering layer may include a light-transmitting adhesive material for bonding the light emitting device and the wavelength conversion portion. The buffering layer may include a double-sided adhesive film, an adhesive material being applied on both sides of the double-sided adhesive film. The third refractive index of the buffering layer may be greater than 1.54 and less than 2.47.

For example, the buffering layer may include a transparent scattering materials. The transparent scattering materials may have a ball type with a diameter of 0.05 μm to 1.0 μm. In addition, the transparent scattering materials may include silica or acrylic. A gap between the transparent scattering materials may be 0.07 μm to 1.39 μm.

For example, the wavelength conversion portion may be disposed to surround the light emitting device. A thickness of the buffering layer disposed between the upper portion of the light emitting device and the wavelength conversion portion may be equal to a thickness of the buffering layer disposed between a side portion of the light emitting device and the wavelength conversion portion.

For example, the buffering layer may include a light-transmitting material.

A lighting apparatus according to another embodiment may include the light emitting device package.

### Advantageous Effects

In the light emitting device package and the lighting apparatus including the same according to the embodiment, the difference in refractive index between the wavelength conversion portion and the light emitting device is reduced because a buffering layer is disposed between the wavelength conversion portion and the light emitting device so that the amount by which light emitted from the light emitting device is total-reflected by the wavelength conversion portion may be reduced, thereby improving luminous flux.

### DESCRIPTION OF DRAWINGS

FIG. 1 is a cross-sectional view of a light emitting device package according to an embodiment.

FIG. 2 is a cross-sectional view of a light emitting device package according to another embodiment.

FIG. 3 is a cross-sectional view of a light emitting device package according to still another embodiment.

FIG. 4 shows a cross-sectional view of a light emitting device package according to a comparative example.

FIG. 5 is a graph for explaining the luminous fluxes of the light emitting devices according to the comparative example and the embodiment.

### BEST MODE

Hereinafter, embodiments will be described in detail with reference to the accompanying drawings, in order to concretely describe the disclosure and to assist in understanding of the disclosure. However, the embodiments disclosed here may be altered into various other forms, and the scope of the disclosure should not be construed as being limited to the embodiments. The embodiments disclosed here are provided in order to more completely describe the disclosure to those of ordinary skill in the art.

In the description of the embodiments, when an element is referred to as being formed “on” or “under” another element, it can be directly “on” or “under” the other element or be indirectly formed with intervening elements therebetween. It will also be understood that “on” or “under” the element may be described relative to the drawings.

In addition, relative terms such as, for example, “first”, “second”, “on/upper/above” and “beneath/lower/below”, used in the following description may be used to distinguish any one substance or element with another substance or element without requiring or containing any physical or logical relationship or sequence between these substances or elements.

In the drawings, the thickness or size of each layer may be omitted or schematically illustrated for clarity and convenience. In addition, the size of each element does not wholly reflect an actual size thereof.

FIG. 1 is a cross-sectional view of a light emitting device package 100A according to an embodiment.

The light emitting device package 100A shown in FIG. 1 may include a base 110, a light emitting device 120, a wavelength conversion portion 130A, a buffering layer 140A, and a lens 150.

The base 110 may be a package body that supports the light emitting device 120, the wavelength conversion portion 130A, the buffering layer 140A, and the lens 150. The package body may be formed of silicon, synthetic resin, or metal.

The base 110 may be a printed circuit board electrically connected to the light emitting device 120, but the embodiment is not limited to the type of the printed circuit board. The printed circuit board may serve to supply power to the light emitting device 120.

The light emitting device 120 may be disposed on the base 110. The light emitting device 120 may be a Light Emitting Diode (LED) chip. The LED chip may include a blue LED chip or ultraviolet LED chip, or may include a package combining at least one or more selected from a group comprised of a red LED chip, green LED chip, blue LED chip, yellow green LED chip, and white LED chip. For example, the light emitting device 120 may emit a light within a blue wavelength band, but the embodiment is not limited thereto.

The light emitting device 120 may be a top emission type, a side emission type, or an omnidirectional emission type. Here, the light emitting device 120 of the top emission type may emit light in the upper direction (for example, a thickness direction of the wavelength conversion portion 130A), the light emitting device 120 of the side emitting type may emit light in the side direction (for example, a direction perpendicular to the upper direction), and the light emitting device 120 of the omnidirectional emission type may emit light both in the upper direction and in the side direction. Hereinafter, the light emitting device 120 may have a first refractive index. As will be described later, when the light emitting device 120 includes a plurality of layers, the first refractive index of the light emitting device 120 may mean the average or median of the refractive indices of the plurality of layers, but the embodiment is not limited thereto.

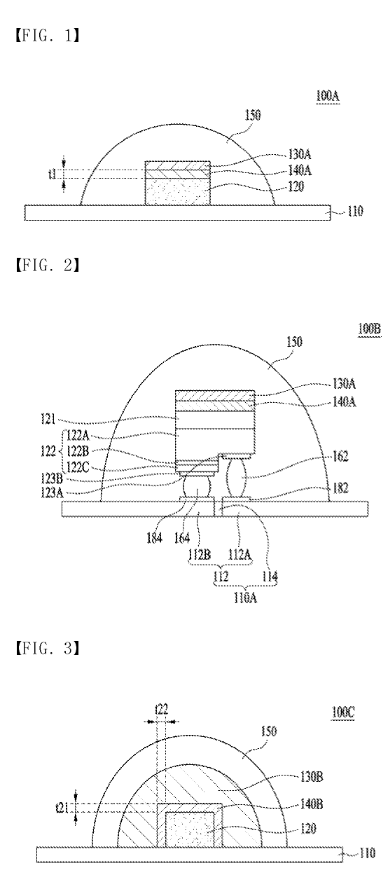

Hereinafter, an example of the light emitting device 120 shown in FIG. 1 will be described with reference to FIG. 2, but the embodiment is not limited thereto.

FIG. 2 is a cross-sectional view of a light emitting device package 100B according to another embodiment.

The light emitting device package 100B shown in FIG. 2 may include a base 110A, a light emitting device 120A, a wavelength conversion portion 130A, a buffering layer 140A, a lens 150, a first bump 162, a second bumps 164, a first metal pad 182, and a second metal pad 184.

The wavelength conversion portion 130A and the buffering layer 140A shown in FIG. 2 are identical to the wavelength conversion portion 130A and the buffering layer 140A shown in FIG. 1, respectively, and thus the same reference numerals are used in FIGS. 1 and 2. The descriptions on the wavelength conversion portion 130A and the buffering layer 140A shown in FIG. 2 are replaced with the descriptions of those shown in FIG. 1, and redundant explanations thereof are omitted.

The base 110A may include a package body 112 and an insulating layer 114. The package body 112 may include a first body portion 112A and a second body portion 112B. The first body portion 112A and the second body portion 112B may be electrically separated from each other by the insulating layer 114. The first and second body portions 112A and 112B may serve to supply power to the light emitting device 120A. In addition, the first and second body portions 112A and 112B may function to increase the light efficiency by reflecting the light generated from the light emitting device 120A and also to discharge a heat generated from the light emitting device 120 into outside. The insulating layer 114 may be formed of an insulating material to electrically isolate the first and second body portions 112A and 112B.

The light emitting device 120A may include a substrate 121, a light emitting structure 122, a first electrode 123A, and a second electrode 123B.

The light emitting structure 122 may be disposed under the substrate 121. The substrate 121 may include a conductive material or a non-conductive material. For example, although the substrate 121 may include at least one of sapphire (Al₂O₃), GaN, SiC, ZnO, GaP, InP, Ga₂O₃, GaAs, or Si.

In order to solve a problem related to the difference in the coefficient of thermal expansion and lattice-mismatching between the substrate 121 and the light emitting structure 122, a buffer layer (or a transition layer) (not illustrated) may be disposed between the two 121 and 122. The buffer layer may include at least one material selected from the group consisting of Al, In, N, and Ga, for example, without being limited thereto. In addition, the buffer layer may have a single-layer or multilayer structure.

The light emitting structure 122 may include a first conductive semiconductor layer 122A, an active layer 122B, and a second conductive semiconductor layer 122C.

The first conductive semiconductor layer 122A may be disposed under the substrate 121. The first conductive semiconductor layer 122A may be formed of a group III-V or II-VI semiconductor compound, which is doped with a first conductive dopant. When the first conductive semiconductor layer 122A is an n-type semiconductor layer, the first conductive dopant may be an n-type dopant and may include Si, Ge, Sn, Se, or Te, without being limited thereto.

For example, the first conductive semiconductor layer 122A may include a semiconductor material having a composition formula of AlₓIn_{y}Ga_{(1-z-y)}N (0≤x≤1, 0≤y≤1, 0≤x+y≤1). The first conductive semiconductor layer 122A may include at least one of GaN, InN, AIN, InGaN, AlGaN, InAlGaN, AlInN, AlGaAs, InGaAs, AlInGaAs, GaP, AlGaP, InGaP, AlInGaP, or InP.

The active layer 122B may be disposed under the first conductive semiconductor layer 122A. The active layer 122B is a layer in which electrons (or holes) introduced through the first conductive semiconductor layer 122A and holes (or electrons) introduced through the second conductive semiconductor layer 122C meet each other to emit light having energy that is determined by the inherent energy band of a constituent material of the active layer 122B.

The active layer 122B may be formed to have at least one of a single-well structure, a multi-well structure, a single-quantum well structure, a multi-quantum well (MQW) structure, a quantum-wire structure, or a quantum dot structure.

The active layer 122B may include a well layer and a barrier layer having a pair structure of any one or more selected from among InGaN/GaN, InGaN/InGaN, GaN/AlGaN, InAlGaN/GaN, GaAs(InGaAs)/AlGaAs, and GaP(InGaP)/AlGaP, without being limited thereto. The well layer may be formed of a material having lower band gap energy than the band gap energy of the barrier layer.

A conductive clad layer (not illustrated) may further be formed on and/or under the active layer 122B. The conductive clad layer may be formed of a semiconductor having higher band gap energy than the band gap energy of the barrier layer of the active layer 122B. For example, the conductive clad layer may include, for example, a GaN, AlGaN, InAlGaN, or super-lattice structure. In addition, the conductive clad layer may be doped to an n-type or a p-type.

The second conductive semiconductor layer 122C may be disposed under the active layer 122B and may be formed of a semiconductor compound such as, for example, a group III-V or II-VI semiconductor compound. For example, the second conductive semiconductor layer 122C may include a semiconductor material having a composition formula of InₓAl_{y}Ga_{(1-x-y)}N (0≤x≤1, 0≤y≤1, 0≤x+y1). The second conductive semiconductor layer 122C may be doped with a second conductive dopant. When the second conductive semiconductor layer 122C is a p-type semiconductor layer, the second conductive dopant may be a p-type dopant and may include Mg, Zn, Ca, Sr, or Ba.

The first conductive semiconductor layer 122A may be configured as an n-type semiconductor layer, and the second conductive semiconductor layer 122C may be configured as a p-type semiconductor layer. Alternatively, the first conductive semiconductor layer 122A may be configured as a p-type semiconductor layer, and the second conductive semiconductor layer 122C may be configured as an n-type semiconductor layer.

The light emitting structure 122 may have any one structure among an n-p junction structure, a p-n junction structure, an n-p-n junction structure, and a p-n-p junction structure.

The first electrode 123A may be disposed under the first conductive semiconductor layer 122A, which is exposed by mesa-etching the second conductive semiconductor layer 122C and the active layer 122B and be electrically connected to the first conductive semiconductor layer 122A. The first electrode 123A may include a material capable of being in ohmic contact to perform the role of the ohmic layer so that a separate ohmic layer (not illustrated) may not be disposed. Alternatively, separate ohmic layer may be disposed under the first electrode 123A.

The second electrode 123B may be disposed under the second conductive semiconductor layer 122C to be electrically connected to the second conductive semiconductor layer 122C.

Each of the first and second electrodes 123A and 123B may be formed of any material that may not absorb the light emitted from the active layer 122B, but that may reflect or transmit the light and that may be grown to a good quality under the first and second conductive semiconductor layers 122A and 122C.

Each of the first and second electrodes 123A and 123B may be formed of a metal, and more specifically may be formed of Ag, Ni, Al, Rh, Pd, Ir, Ru, Mg, Zn, Pt, Au, Hf, or a selective combination thereof.

In particular, the second electrode 123B may be a transparent conductive oxide (TCO) layer. For example, the second electrode 123B may include at least one of the aforementioned metal, indium tin oxide (ITO), indium zinc oxide (IZO), indium zinc tin oxide (IZTO), indium aluminum zinc oxide (IAZO), indium gallium zinc oxide (IGZO), indium gallium tin oxide (IGTO), aluminum zinc oxide (AZO), antimony tin oxide (ATO), gallium zinc oxide (GZO), IrOx, RuOx, RuOx/ITO, Ni/IrOx/Au, or Ni/IrOx/Au/ITO, but is not limited to these materials. The second electrode 123B may include a material that makes an ohmic contact with the second conductive semiconductor layer 122C which may be made of GaN.

In addition, the second electrode 123B may be formed as a single layer or multiple layers by a reflective electrode material having an ohmic characteristic. When the second electrode 123B performs the role of the ohmic layer, a separate ohmic layer (not illustrated) may not be formed.

Since the light emitting device package 100B illustrated in FIG. 2 has a flip-chip bonding structure, the light emitted from the active layer 122B is emitted through the substrate 121 and the first conductive semiconductor layer 122A. For this, the substrate 121 and the first conductive semiconductor layer 122A may be made of a light-transmitting material, and the second conductive semiconductor layer 122C and the second electrode 123B may be made of a light-transmitting material or a light non-transmitting material.

In addition, the first bump 162 may be disposed between the first electrode 123A and the first metal pad 182 to electrically connect the first bump 162 and the first electrode 123A. The second bump 164 may be disposed between the second electrode 123B and the second metal pad 184 to electrically connect the second electrode 123B and the second metal pad 184.

The first electrode 123A may be electrically connected to the first metal pad 182 through the first bump 162 and the second electrode 123B may be electrically connected to the second metal pad 184 through the second bump 164.

Although not shown, a first upper bump metal layer (not shown) may be further disposed between the first electrode 123A and the first bump 162 and a first lower bump metal layer (not shown) may be further disposed between the first metal pad 182 and the first bump 162. Here, the first upper bump metal layer and the first lower bump metal layer play the role of marking the position at which the first bump 162 is to be disposed. Similarly to that, a second upper bump metal layer (not shown) may be further disposed between the second electrode 123B and the second bump 164 and a second lower bump metal layer (not shown) may be further disposed between the second metal pad 184 and the second bump 164. Here, the second upper bump metal layer and the second lower bump metal layer play the role of marking the position at which the second bump 164 is to be disposed.

The first metal pad 182 may be electrically connected to the first body portion 112A and the second metal pad 184 may be electrically connected to the second body portion 112B.

Each of the first and second metal pads 182 and 184 may be formed of a metal and may be formed of a reflective electrode material having an ohmic characteristic. For example, each of the first and second metal pads 182 and 184 may include at least one of aluminum (Al), titanium (Ti), chrome (Cr), nickel (Ni), copper (Cu), or gold (Au), and may be formed to have a structure such as a single layer or multiple layers.

The light emitting device package 100B shown in FIG. 2 has a flip chip bonding structure, but the embodiment is not limited thereto. That is, the light emitting device 120A shown in FIG. 2 is merely an example of the light emitting device 120 shown in FIG. 1, and the light emitting device 120 shown in FIG. 1 is not limited to the structure shown in FIG. 2. That is, the light emitting device 120 shown in FIG. 1 may have a vertical bonding structure or a horizontal bonding structure unlike the light emitting device 120A shown in FIG. 2. Of course, the structure of the base 110 may be changed to fit the bonding structure of the light emitting device 120.

FIG. 3 shows a cross-sectional view of a light emitting device package 100C according to still another embodiment.

The light emitting device package 100C shown in FIG. 3 may include a base 110, a light emitting device 120, a wavelength conversion portion 130B, a buffering layer 140B, and a lens 150. The base 110 and the light emitting device 120 shown in FIG. 3 are identical to the base 110 and the light emitting device 120 shown in FIG. 1, respectively, and thus the same reference numerals are used in FIGS. 1 and 3. Therefore, redundant description will be omitted. Also, the light emitting device 120 shown in FIG. 3 may be implemented as shown in FIG. 2, but embodiments are not limited thereto.

The wavelength conversion portion 130A or 130B may be disposed on the light emitting device 120 or 120A. The wavelength conversion portion 130A or 130B 90 may have a second refractive index. The wavelength conversion portion 130A or 130B may be formed of, for example, silicon (Si), and may convert the wavelength of light emitted from the light emitting device 120 or 120A because it includes a fluorescent substance (or, phosphorescent substance). Although the fluorescent substance may include a fluorescent material of any wavelength conversion portion that may convert the light generated in the light emitting device 120 into white light such as a YAG-based, TAG-based, silicate-based, sulfide-based, or nitride-based fluorescent substance, the embodiment is not limited as to the type of the fluorescent substance.

The YAG-based and TAG-based fluorescent materials may be selected from among (Y, Tb, Lu, Sc, La, Gd, Sm) 3 Al, Ga, In, Si, Fe) 5 (O, S) 12:Ce, and the silicate-based fluorescent material may be selected from among (Sr, Ba, Ca, Mg) 2SiO₄: (Eu, F, Cl).

In addition, the sulfide-based fluorescent material may be selected from among (Ca, Sr)S:Eu and (Sr, Ca, Ba) (Al, Ga) 2S4:Eu, and the nitride-based fluorescent substance may be selected from among (Sr, Ca, Si, Al, O) N:Eu (e.g. CaAlSiN4:Eu β-SiAlON:Eu) and (Cax, My) (Si, Al) 12 (O,N) 16, which is based on Ca-α SiAlON:Eu (where M is at least one material of Eu, Tb, Yb, or Er, 0.05<(x+y)<0.3, 0.02<x<0.27 and 0.03<y<0.3).

As a red fluorescent substance, a nitride-based fluorescent substance including N (e.g. CaAlSiN₃:Eu) may be used. Such a nitride-based red fluorescent substance may have higher reliability with respect to the external environment such as, for example, heat and moisture, and lower discoloration possibility than a sulfide-based fluorescent substance.

For example, when it is desired to emit white light from the light emitting device package 100A, 100B, or 100C including the light emitting device 120 or 120A emitting blue light, the wavelength conversion portion 130A or 130B may include a yellow phosphor, a red phosphor and a green phosphor at the same time, or all of a yellow phosphor, a red phosphor, and a green phosphor.

According to one embodiment, as shown in FIG. 1, the wavelength conversion portion 130A may be disposed on the light emitting device 120 in the form of a film. In this case, the light emitting device 120 may be a top emitting type. In addition, the light emitted through the upper portion of the light emitting device 120 may be emitted in the upper direction through the buffering layer 140A and the wavelength conversion portion 130A. If the wavelength conversion portion 130A is implemented in a film form, the buffering layer 140A may be easily disposed between the wavelength conversion portion 130A and the light emitting device 120.

According to another embodiment, as shown in FIG. 3, the wavelength conversion portion 130B may be disposed to surround the light emitting device 120. In this case, the light emitting device 120 may be the omni-directional emitting type. Therefore, the light emitted in the upper direction and in the side direction of the light emitting device 120 may be emitted both in the upper direction and in the side direction through the buffering layer 140B and the wavelength conversion portion 130B.

Besides, although not shown in FIGS. 1 to 3, it goes without saying that the wavelength conversion portion 130A or 130B may have a various shape as long as the wavelength of light emitted from the light emitting device 120 or 120A may be changed.

Meanwhile, the buffering layer 140A or 140B is disposed between the light emitting device 120 or 120A and the wavelength conversion portion 130A or 130B, and may have a third refractive index. Here, the third refractive index may be a value between the first refractive index of the light emitting device 120 and the second refractive index of the wavelength conversion portion 130A or 130B.

In addition, the third refractive index may be smaller than the first refractive index and larger than the second refractive index. Alternatively, the third refractive index may be smaller than the second refractive index and greater than the first refractive index.

In addition, the buffering layer 140A or 140B may include at least one of silicon, TiO₂, BaTiO₃, or ZrO₂, but the embodiments are not limited thereto. That is, the material of the buffering layer 140A or 140B may include a light-transmitting material having a third refractive index of a value between the first refractive index and the second refractive index.

For example, when the light emitting device 120 or 120A is made of GaN emitting blue light, the first refractive index may be 2.47. Also, when the wavelength conversion portion 130A or 130B includes a phosphor, the second refractive index may be 1.54. In this case, the buffering layer 140A or 140B may be implemented with a silicon material having a third refractive index greater than 1.54 and less than 2.47.

Also, when the thickness t1, t21, or t22 of the buffering layer 140A or 140B is less than 50 μm, it may be difficult to manufacture the buffering layer 140A or 140B in view of the process margin. Or, when the thickness t1, t21, or t22 of the buffering layer 140A or 140B is larger than 70 μm, the buffering layer 140A or 140B may absorb light, thereby lowering the luminous flux of the light emitting device package 100A, 100B, or 100C. Therefore, the thickness t1, t21, or t22 of the buffering layer 140A or 140B may be 50 μm to 70 μm, but the embodiments are not limited thereto.

In addition, referring to FIG. 3, the thickness t21 of the buffering layer 140B disposed on the upper portion of the light emitting device 120 and the thickness t22 of the buffering layer 140B disposed on the side of the light emitting device 120 may be equal to or different from each other. If the thicknesses t21 and t22 are equal to each other, the light emitted from the light emitting device 120 may be uniformly emitted to the top and side portions.

In addition, the buffering layer 140A or 140B may include a light-transmitting adhesive material for bonding the light emitting device 120 or 120A and the wavelength conversion portion 130A or 130B. For example, the buffering layer 140A or 140B may be embodied as a double-sided adhesive film coated with an adhesive material on both sides thereof. If the buffering layer 140A or 140B is realized as the double-sided adhesive film, one surface of the double-sided adhesive film may be adhesively bonded to the light emitting device 120 or 120A, and the other surface of the double-sided adhesive film may be adhesively bonded to the wavelength conversion portion 130A or 130B. In this case, a separate adhesive for bonding the light emitting device 120, the wavelength conversion portion 130A or 130B, and the buffering layer 140A or 140B to each other is not required.

In addition, the buffering layer 140A or 140B may include a transparent scattering material. The transparent scattering material may include a ball-type silica or acryl having a diameter of 0.05 μm to 1.0 μm. The gap between the transparent scattering materials may maintain 0.07 μm to 1.39 μm. When the transparent scattering material is included in the buffering layer 140A or 140B, light is scattered, thereby improving the light extraction efficiency.

In addition, the lens 150 may be disposed to surround the light emitting device 120 or 120A and the wavelength conversion portion 130A or 130B on the base 110 or 110A. As shown in FIGS. 1 to 3, the lens 150 may have a hemispherical cross-sectional shape, but the embodiment is not limited to the specific cross-sectional shape of the lens 150. In addition, the lens 150 may be formed of a material having a fourth refractive index of 1.54, but the embodiment is not limited to the material of the lens 150. In some cases, the lens 150 may be omitted.

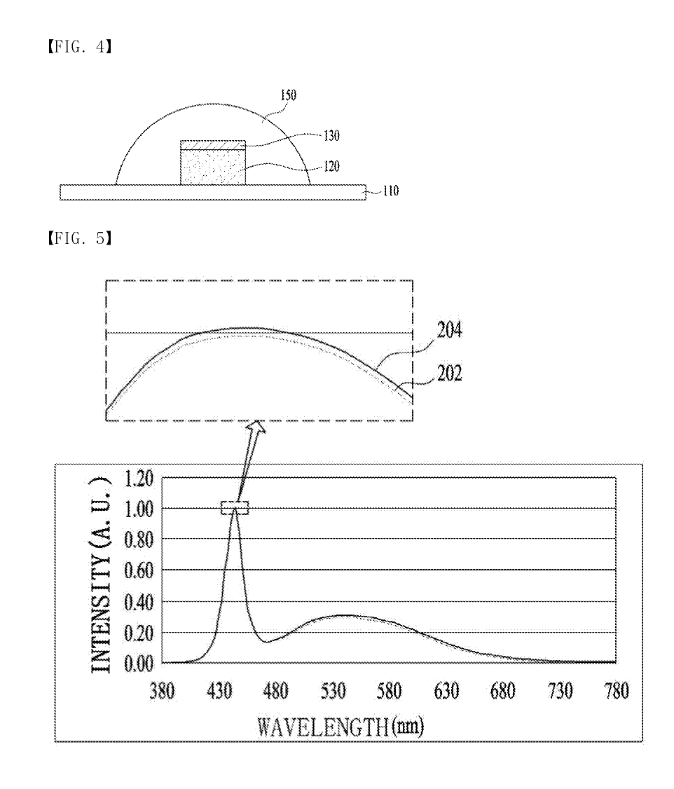

FIG. 4 shows a cross-sectional view of a light emitting device package according to a comparative example.

The light emitting device package according to the comparative example shown in FIG. 4 may include a base 110, a light emitting device 120, a wavelength conversion portion 130, and a lens 150. Unlike the light emitting device package 100A shown in FIG. 1, the light emitting device package according to the comparative example shown in FIG. 4 does not include any buffering layer. Except for this, since the light emitting device package shown in FIG. 4 is the same as the light emitting device package 100A shown in FIG. 1, a duplicate description will be omitted. That is, the base 110, the light emitting device 120, the wavelength conversion portion 130, and the lens 150 shown in FIG. 4 correspond to the base 110, the light emitting device 120, the wavelength conversion portion 130A, and the lens 150 shown in FIG. 1, respectively.

FIG. 5 is a graph for explaining the luminous fluxes of the light emitting devices according to the comparative example and the embodiment. Here, the horizontal axis represents the wavelength and the vertical axis represents the light intensity (i.e., intensity or luminous flux).

In the case of the light emitting device package shown in FIG. 4, light emitted from the light emitting device 120 is emitted with passing through the wavelength conversion portion 130. At this time, when the difference between the first refractive index of the light emitting device 120 and the second refractive index of the wavelength conversion portion 130 are large, the light emitted from the light emitting device 120 may not be escaped because the light is total-reflected by the wavelength conversion portion 130. Therefore, the luminous flux may be lowered.

On the other hand, in the case of the light emitting device package 100A, 100B or 100C according to the embodiment, the light emitted from the light emitting device 120 is directed to the wavelength conversion portion 130A or 130B via the buffering layer 140A or 140B. Here, since the third refractive index of the buffering layer 140A or 140B is a value between the first refractive index of the light emitting device 120 or 120A and the second refractive index of the wavelength conversion portion 130A or 130B, the light emitted from the light emitting device 120 may be output through the wavelength conversion portion 130A or 130B without being total-reflected by the buffering layer 140A or 140B.

Accordingly, as shown in FIG. 5, the intensity 204 of light emitted from the light emitting device package 100A, 100B, or 100C according to the embodiment may greater than the intensity 202 of light emitted from the light emitting device package according to the comparative example. Referring to FIG. 5, it is known that the luminous flux 204 of light emitted from the light emitting device package 100A, 100B, or 100C according to embodiment may be more improved by about 2% than that 202 of the comparative example.

As a result, in the case of the light emitting device packages 100A, 100B, and 100C according to the embodiments, the difference between the refractive index of the light emitting device 120 or 120A and the refractive index of the wavelength conversion portion 130A or 130B is reduced because the buffering layer 140A or 140B is disposed between the wavelength conversion portion 130A or 130B and the light emitting device 120 or 120A. Therefore, the amount by which light emitted from the light emitting devices 120 and 120A is total-reflected by the wavelength conversion portion 130A or 130B may be reduced, thereby improving light amount (or, luminous flux).

A plurality of light emitting device packages according to the embodiment may be arranged on a board, and optical members such as, for example, a light guide plate, a prism sheet, and a diffuser sheet may be disposed on the optical path of the light emitting device package. The light emitting device packages, the board, and the optical members may function as a backlight unit.

In addition, the light emitting device package according to the embodiment may be applied to (or, used for) a display apparatus, an indicator apparatus, and a lighting apparatus.

Here, the display apparatus may include a bottom cover, a reflector disposed on the bottom cover, a light emitting module including the light emitting device package according to the embodiment and emitting light, a light guide plate disposed in front of the reflector to guide light emitted from the light emitting module forward, an optical sheet including prism sheets disposed in front of the light guide plate, a display panel disposed in front of the optical sheet, an image signal output circuit connected to the display panel to supply an image signal to the display panel, and a color filter disposed in front of the display panel. Here, the bottom cover, the reflector, the light emitting module, the light guide plate, and the optical sheet may form a backlight unit.

In addition, the lighting apparatus may include a light source module that includes a board and the light emitting device package according to the embodiment, a radiator that dissipates heat of the light source module, and a power supply unit that processes or converts an electrical signal received from the outside to provide the same to the light source module. For example, the lighting apparatus may include a lamp, a headlamp, or a street light.

The headlamp may include a light emitting module that includes light emitting device package according to the embodiment disposed on a board, a reflector that reflects light emitted from the light emitting module in a given direction, for example, in the forward direction, a lens that refracts light reflected by the reflector forward, and a shade that blocks or reflects some of the light, which has been reflected by the reflector to thereby be directed to the lens, so as to realize the light distribution pattern desired by a designer.

The above description merely describes the technical spirit of the embodiments by way of example, and various modifications and substitutions related to the above description are possible by those skilled in the art without departing from the scope and spirit of the disclosure. Accordingly, the disclosed embodiments are provided for the purpose of description and are not intended to limit the technical scope of the disclosure, and the technical scope of the disclosure is not limited by the embodiments. The range of the disclosure should be interpreted based on the following claims, and all technical ideas that fall within the range equivalent to the claims should be understood as belonging to the scope of the disclosure.

### [Mode for Invention]

Various embodiments have been described in the best mode for carrying out the invention.

### INDUSTRIAL APPLICABILITY

The light emitting device package according to the embodiment may be applied to (or, used for) a display device, a pointing device, or a lighting apparatus such as a lamp, a head lamp, and a streetlight.

1. A light emitting device package, comprising:
a base;
a light emitting device disposed on the base and having a first refractive index;
a wavelength conversion portion disposed on the light emitting device and having a second refractive index; and
a buffering layer disposed between the light emitting device and the wavelength conversion portion, having a third refractive index between the first refractive index and the second refractive index, and including a transparent scattering materials.

2. The light emitting device according to claim 1, wherein the third refractive index is smaller than the first refractive index and larger than the second refractive index.

3. The light emitting device according to claim 1, wherein the third refractive index is smaller than the second refractive index and larger than the first refractive index.

4. The light emitting device according to claim 1, wherein the buffering layer comprises at least one of silicon, TiO₂, BaTiO₃, or ZrO₂.

5. The light emitting device according to claim 1, wherein the wavelength conversion portion has a film shape.

6. The light emitting device according to claim 1, wherein the buffering layer has a thickness of 50 μm to 70 μm.

7. The light emitting device according to claim 1, further comprising a lens disposed on the base to surround the light emitting device and the wavelength conversion portion.

8. The light emitting device according to claim 1, wherein the light emitting device emits a light within a blue wavelength band.

9. The light emitting device according to claim 1, wherein the buffering layer includes a light-transmitting adhesive material for bonding the light emitting device and the wavelength conversion portion.

10. The light emitting device according to claim 1, wherein the buffering layer comprises a double-sided adhesive film, an adhesive material being applied on both sides of the double-sided adhesive film, and
wherein the double-sided adhesive film comprises:
one surface adhesively bonded to the light emitting device; and
the other surface adhesively bonded to the wavelength conversion portion.

11. The light emitting device according to claim 1, wherein the third refractive index of the buffering layer is greater than 1.54 and less than 2.47.

12. (canceled)

13. The light emitting device according to claim 1, wherein the wavelength conversion portion is disposed to surround the light emitting device.

14. The light emitting device according to claim 1, wherein the buffering layer comprises a light-transmitting material.

15. The light emitting device according to claim 13, wherein a thickness of the buffering layer disposed between the upper portion of the light emitting device and the wavelength conversion portion is equal to a thickness of the buffering layer disposed between a side portion of the light emitting device and the wavelength conversion portion.

16. The light emitting device according to claim 1, wherein the transparent scattering materials have a ball type with a diameter of 0.05 μm to 1.0 μm.

17. The light emitting device according to claim 1, wherein the transparent scattering materials comprise silica or acrylic.

18. The light emitting device according to claim 1, wherein a gap between the transparent scattering materials is 0.07 μm to 1.39 μm.

19. The light emitting device according to claim 7, wherein the lens has a hemispherical cross-sectional shape.

20. A lighting apparatus comprising the light emitting device package according to claim 1.

21. The light emitting device according to claim 7, wherein the second refractive index of the wavelength conversion portion is the same as a refractive index of the lens.
